(19) United States
(12) Patent Application Publication
(10) Pub. No.: US 2022/0312657 A1
(43) Pub. Date: Sep. 29, 2022

(54) HIGH-FREQUENCY CABLE WITH STABLE STRUCTURE

(71) Applicant: CHANGSHU JHOSIN COMMUNICATION TECHNOLOGY CO., LTD, Jiangsu (CN)

(72) Inventors: Yuhui LIU, Jiangsu (CN); Jun YAN, Jiangsu (CN)

(73) Assignee: CHANGSHU JHOSIN COMMUNICATION TECHNOLOGY CO., LTD, Jiangsu (CN)

(21) Appl. No.: 17/286,948

(22) PCT Filed: Jun. 23, 2020
(86) PCT No.: PCT/CN2020/097620

§ 371 Date: Apr. 20, 2021

(30) Foreign Application Priority Data
May 27, 2020 (CN) 202020914313.9

(51) Int. Cl. H05K 9/00; H01B 11/00

(52) U.S. Cl. CPC H05K 9/0098; H01B 11/002; H01B 7/17

(57) ABSTRACT

Disclosed is a high-frequency cable, in particular, a high-frequency cable with a stable structure, including: two signal cables arranged in parallel; one ground cable located between the two signal cables or two ground cables respectively located on lateral sides of the two signal cables, and axes of the two signal cables and axes of the two ground cables being located on the same plane; a fastening layer wrapped outside the two signal cables and the ground cable, and configured to fasten the two signal cables and the ground cable; a shielding layer wrapped outside the fastening layer; and a sheath layer wrapped on the shielding layer. The high-frequency cable with a stable structure provided by the present disclosure features a stable structure, is easy to process, reduces production costs, and provides good electrical performance.

### TECHNICAL FIELD

The present disclosure relates to a high-frequency cable, and in particular, to a high-frequency cable with a stable structure.

### BACKGROUND

In a conventional 30 GHz high-frequency cable structure, two signal cables are arranged in parallel, one ground cable is added on a side of the signal cables instead of in between them, and then the cables are longitudinally wrapped with aluminum foil. For this type of product, the ground cable easily deviates from its position during longitudinal wrapping with aluminum foil, making it hard to control production and causing high manufacturing costs.

### SUMMARY

To resolve the foregoing problem, the present disclosure provides a high-frequency cable with a stable structure, which features a stable structure, is easy to produce, and reduces production costs. A specific technical solution is as follows:

A high-frequency cable with a stable structure includes: two signal cables arranged in parallel; one ground cable located between the two signal cables or two ground cables respectively located on lateral sides of the two signal cables, and axes of the two signal cables and axes of the two ground cables being located on the same plane; a fastening layer wrapped outside the two signal cables and the ground cable, and configured to fasten the two signal cables and the ground cable; a shielding layer wrapped outside the fastening layer; and a sheath layer wrapped on the shielding layer.

In the foregoing technical solution, two ground cables can be used to form a symmetric structure that is uniformly stressed. The fastening layer is used to fasten the signal cables and the ground cables, and positions of the ground cables will not be deviated.

As the two signal cables are close to each other, a position of the ground cable will not be deviated and will be stable when the ground cable is located between the two signal cables.

Further, the shielding layer is one of an aluminum foil layer, a copper foil layer, or a metal braided layer, and the shielding layer is connected to the ground cable.

Further, the shielding layer is a longitudinal wrapping layer.

With the foregoing technical solution, longitudinal wrapping can increase a transmission frequency.

Further, a coverage rate of the fastening layer is greater than 0 and less than 100%, aluminum foil or copper foil of the shielding layer is located on one side of the helical wrapping layer, and the aluminum foil or the copper foil is connected to the ground cable.

With the foregoing technical solution, the coverage rate of the fastening layer being greater than 0 and less than 100% enables the covered ground cable to reach contact with the peripheral aluminum foil, thereby facilitating signal transmission and achieving better performance.

Further, the fastening layer is PET or another material.

With the foregoing technical solution, the fastening layer is close to the shielding layer, and this can implement automatic processing at a time, thereby improving processing efficiency.

Further, aluminum foil or copper foil of the shielding layer is located on one side of the fastening layer, and the fastening layer is provided with an open area, hole, or groove used for connecting the aluminum foil or the copper foil to the ground cable.

With the foregoing technical solution, the ground cable is connected to the peripheral aluminum foil, and this facilitates signal transmission and achieves better performance.

Further, the fastening layer is PET or another material, and the fastening layer is close to the shielding layer.

Further, the sheath layer is a hot melt mylar layer or another material, or may be an extruded sheath.

Compared with the existing technology, the present disclosure has the following beneficial effects.

The high-frequency cable with a stable structure provided by the present disclosure features a stable structure, is easy to process, reduces production costs, and provides good electrical performance.

### BRIEF DESCRIPTION OF DRAWINGS

FIG. 1 is a sectional view of Embodiment 1;

FIG. 2 is a schematic structural diagram of Embodiment 1;

FIG. 3 is a sectional view of Embodiment 2; and

FIG. 4 is a schematic structural diagram of Embodiment 2.

### DETAILED DESCRIPTION

The present disclosure is further described with reference to the accompanying drawings.

### Embodiment 1

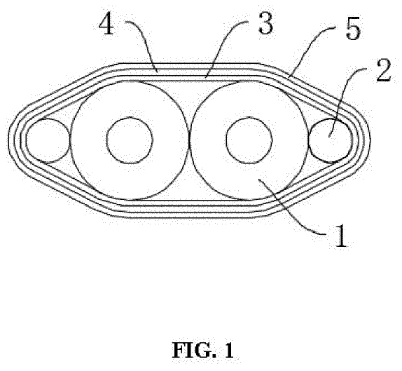

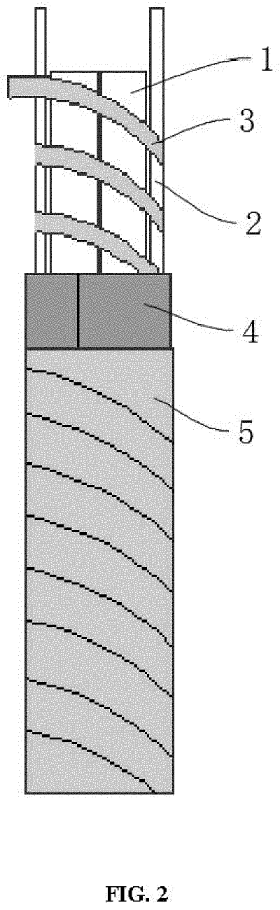

As shown in FIG. 1 and FIG. 2, a high-frequency cable with a stable structure includes two signal cables 1 arranged in parallel, and further includes two symmetrically disposed ground cables 2 that are respectively located on lateral sides of the two signal cables 1, where axes of the two signal cables 1 and those of the two ground cables 2 are located on the same plane; a fastening layer 3, where the fastening layer 3 is wrapped outside the two signal cables 1 and the two ground cables 2, and the fastening layer 3 is configured to fasten the two signal cables 1 and the two ground cables 2; a shielding layer 4, where the shielding layer 4 is wrapped outside the helical wrapping layer 3; and a sheath layer 5, where the sheath layer 5 is wrapped on the shielding layer 4.

Two ground cables 2 are used to form a symmetric structure that is uniformly stressed. The fastening layer 3 is used to fasten the signal cables 1 and the ground cables 2. With this fastening manner, positions of the ground cables 2 will not be deviated, thereby effectively solving the problem of position deviation in case that a single ground cable 2 is longitudinally wrapped, and enabling easy processing and reducing processing costs.

The shielding layer 4 is one of an aluminum foil layer, a copper foil layer, or a tinned copper braided layer, and the shielding layer 4 is connected to the ground cables 2.

The shielding layer 4 is a longitudinal wrapping layer. Longitudinal wrapping can increase a transmission frequency.

The fastening layer 3 is a helical wrapping layer. A coverage rate of the fastening layer 3 is greater than 0 and less than 100%, aluminum foil or copper foil of the shielding layer 4 is located on one side of the fastening layer 3, and the aluminum foil or the copper foil is connected to the ground cables 2.

The coverage rate of the fastening layer 3 greater than 0 and less than 100% enables the covered ground cables 2 to reach contact with the peripheral aluminum foil, thereby facilitating signal transmission and achieving better performance.

The coverage rate of the fastening layer 3 being greater than 0 and less than 100% indicates that if filaments are used for helical wrapping, the coverage rate of the fastening layer 3 is close to 0; or if helical wrapping using a helical wrap tape is performed in a manner that facilitates edge contact, the coverage rate of the fastening layer 3 is close to 100%, provided that the shielding layer 4 can be connected to the ground cables 2.

The fastening layer 3 may be a PET layer or another material, and is bonded to the shielding layer 4. The fastening layer 3 is bonded to the shielding layer 4, and this can implement automatic processing at a time, thereby improving processing efficiency.

The fastening layer 3 is close to a metal braided mesh, aluminum foil, or copper foil. The metal braided mesh, the aluminum foil, or the copper foil is connected to the ground cables 2, and this facilitates signal transmission and achieves better performance.

The sheath layer 5 is a hot melt mylar layer or another material, or may be an extruded sheath.

### Embodiment 2

This embodiment differs from Embodiment 1 in that the fastening layer 3 is provided with an open area, hole, or groove configured for connecting the metal braided layer, the aluminum foil, or the copper foil to the ground cables 2.

With the open area, hole, or groove for connection, the fastening layer 3 does not completely isolate the ground cables 2 from the shielding layer 4, so that the ground cables 2 can be connected to the shielding layer 4, thereby ensuring stable performance.

Specifically, the fastening layer 3 may be a PET layer or another material, and is close to the shielding layer 4.

### Embodiment 3

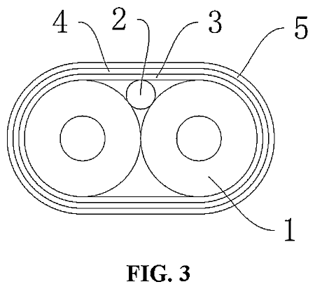

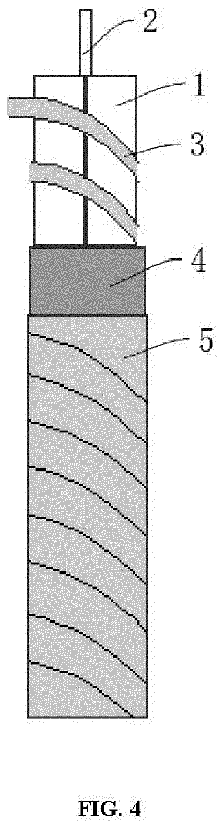

As shown in FIG. 3 and FIG. 4, this embodiment differs from Embodiment 1 in that one ground cable 2 is provided in this embodiment, and the ground cable 2 is located between two signal cables 1.

As the two signal cables 2 are close to each other, a position of the ground cable 1 will not be deviated and will be stable when the ground cable 1 is located between the two signal cables 2.

### Electrical Performance (3 m)

| Attenuation | 1 GHz | −4.8 dB/cable |
|---|---|---|
| | 2.5 GHz | −7 dB/cable |
| | 5 GHz | −8.5 dB/cable |
| | 10 GHz | −12.0 dB/cable |
| | 15 GHz | −14.5 dB/cable |
| | 20 GHz | −18.0 dB/cable |
| | 25 GHz | −22 dB/cable |
| Impedance | 9.8-101.5Ω | |
| SCD21 | 0-25 GHz | −22 dB/cable |

| | |
|---|---|
| SKEW | 11 PS/cable |
| DELAY | 15.3 ns/cable |

The high-frequency cable with a stable structure provided by the present disclosure features a stable structure, is easy to process, reduces production costs, and provides good electrical performance.

What is claimed is:

1. A high-frequency cable with a stable structure, comprising:
two signal cables arranged in parallel,
one ground cable located between the two signal cables or two ground cables respectively located on lateral sides of the two signal cables, and axes of the two signal cables and axes of the two ground cables being located on the same plane;
a fastening layer wrapped outside the two signal cables and the ground cable, and configured to fasten the two signal cables and the ground cable;
a shielding layer wrapped outside the fastening layer; and
a sheath layer wrapped on the shielding layer.

2. The high-frequency cable with a stable structure of claim 1, wherein the shielding layer is one of an aluminum foil layer, a copper foil layer, and a metal braided layer, and the shielding layer is connected to the ground cable.

3. The high-frequency cable with a stable structure of claim 2, wherein a coverage rate of the fastening layer is greater than 0 and less than 100%, aluminum foil or copper foil of the shielding layer is located on one side of the fastening layer, and the aluminum foil or the copper foil is connected to the ground cable.

4. The high-frequency cable with a stable structure of claim 2, wherein aluminum foil or copper foil of the shielding layer is located on one side of the fastening layer, and the fastening layer is provided with an open area, hole, or groove for connecting the aluminum foil or the copper foil to the ground cable.
